(19) United States
(12) Patent Application Publication
(10) Pub. No.: US 2010/0279435 A1
(43) Pub. Date: Nov. 4, 2010

(54) TEMPERATURE CONTROL OF CHEMICAL MECHANICAL POLISHING

(75) Inventors: Kun Xu, Sunol, CA (US); Jimin Zhang, San Jose, CA (US); Stephen Jew, San Jose, CA (US); Thomas H. Osterheld, Mountain View, CA (US)

Correspondence Address: FISH & RICHARDSON P.C., P.O. BOX 1022, MINNEAPOLIS, MN, 55440-1022, US

(73) Assignee: Applied Materials, Inc.

(21) Appl. No.: 12/433,559

(22) Filed: Apr. 30, 2009

(51) Int. Cl. H01L 21/66; C23F 1/08

(52) U.S. Cl. 438/5; 156/345.13; 257/E21.525

(57) ABSTRACT

A chemical mechanical polishing apparatus including a platen for holding a pad having a polishing surface, a subsystem for holding a substrate and the polishing surface together during a polishing step, and a temperature sensor oriented to measure a temperature of the polishing surface, wherein the subsystem accepts the temperature measured by the sensor and is programmed to vary a polishing process parameter in response to the measured temperature. In an aspect, a chemical mechanical polishing apparatus having a platen for holding a pad having a polishing surface, a fluid delivery system for transporting a fluid from a source to the polishing surface, and a temperature controller which during operation controls the temperature of the fluid transported by the delivery system.

### TECHNICAL FIELD

This invention relates to methods and apparatus for chemical mechanical polishing (CMP) of semiconductor substrates, and more particularly to temperature control during such chemical mechanical polishing.

### BACKGROUND

Integrated circuits are typically formed on substrates, such as silicon wafers, by the sequential deposition of various layers such as conductive, semiconductor or insulating layers. After a layer is deposited, a photoresist coating can be applied on top of the layer. A photolithographic apparatus, which operates by focusing a light image on the coating, can be used to remove portions of the coating, leaving the photoresist coating on areas where circuitry features are to be formed. The substrate can then be etched to remove the uncoated portions of the layer, leaving the desired circuitry features.

As a series of layers are sequentially deposited and etched, the outer or uppermost surface of the substrate tends to become increasingly non-planar. This non-planar surface presents problems in the photolithographic steps of the integrated circuit fabrication process. For example, the ability to focus the light image on the photoresist layer using the photolithographic apparatus may be impaired if the maximum height difference between the peaks and valleys of the non-planar surface exceeds the depth of focus of the apparatus. Therefore, there is a need to periodically planarize the substrate surface.

Chemical mechanical polishing (CMP) is one accepted method of planarization. Chemical mechanical polishing typically includes mechanically abrading the substrate in a slurry that contains a chemically reactive agent. During polishing, the substrate is typically held against a polishing pad by a carrier head. The polishing pad may rotate. The carrier head may also rotate and move the substrate relative to the polishing pad. As a result of the motion between the carrier head and the polishing pad, chemicals, which can include a chemical solution or chemical slurry, planarize the non-planar substrate surface by chemical mechanical polishing.

The CMP process, designed to remove nonplanarity, nevertheless can lead to non-planar artifacts. For example, the fluid dynamics of the slurry, coupled with the mechanical aspects of the system can lead to turbulence variations across the polishing pad/substrate, proportional to the relative speed of rotation. These turbulence variations are believed to lead to erosion in the substrate which can result in deviations from planarity, contrary to the goal of the CMP. This erosion can be countered in part by also moving the substrate in relation to the CMP polishing pad, but such erosion is not entirely eliminated. Another defect or deviation in planarity which can arise from CMP is “dishing” or differential polishing and/or erosion which occurs between different material layers, typically material layers of different hardness. For example, when CMP breaks through an overlying hard layer, e.g. of oxide, an underlying layer of softer metal can be “dished.” Consequently, there is a need in the art to improve the ability of CMP to planarize a substrate and to reduce non-planar side-effects of CMP such as erosion and dishing.

### SUMMARY

Applicants have discovered that controlling temperature during CMP can lead to improved planarization, reduced erosion, and reduced dishing. In particular, Applicants have discovered that, for example, in CMP of copper using a slurry with ammonium persulphate (APS) oxidizer, dishing and erosion can depend on the temperature at the surface of a polishing pad and the temperature of the polishing slurry, where dishing is increased with decreasing temperature, whereas erosion is increased with increasing temperature.

In general, in various aspects, the invention features a chemical mechanical polishing apparatus with a platen for holding a pad having a polishing surface, a subsystem for holding a substrate against the polishing surface during a polishing process, and a temperature sensor oriented to measure a temperature of the polishing surface. The subsystem accepts the temperature measured by the sensor and is programmed to vary a polishing process parameter in response to the measured temperature.

Various implementations may include one or more or the following. The subsystem may hold the substrate against the polishing surface with a controlled pressure, and the polishing process parameter may be the controlled pressure. A carrier head may hold the substrate. A pressure controller may control the pressure with which the subsystem holds the substrate against the polishing surface. A processor may be electrically connected to the pressure controller. The pressure controller may control the pressure by regulating a flow of compressed fluid to the carrier head. A relative velocity between the substrate and the polishing surface may be the polishing process parameter. A chemical solution delivery system may deliver a chemical solution with a concentration to the polishing surface, and the polishing process parameter may be the concentration.

In some aspects, a chemical mechanical polishing apparatus has a platen for holding a pad having a polishing surface, a fluid delivery system for transporting a fluid from a source to the polishing surface, and a temperature controller which during operation controls the temperature of the fluid transported by the delivery system.

Several implementations may include one or more of the following. A heating/cooling element may adjust the temperature of the fluid. The apparatus may have a processor for controlling the temperature of the fluid. The source from which the fluid is transported may be a water tank.

In various aspects, a method for polishing a surface of a substrate includes polishing the surface of the substrate with a polishing surface during a polishing process characterized by a plurality of process parameters, repeatedly monitoring a temperature of the polishing surface during the polishing process, and controlling one of the plurality of process parameters in response to the monitored temperature so as to achieve a target value for the monitored temperature.

Some implementations may include one or more of the following. One of the plurality of process parameters may be a controlled pressure with which the substrate is held against the polishing surface. The pressure may be increased if the monitored temperature is below the target temperature, and the pressure may be decreased if the monitored temperature is above the target temperature. One of the plurality of process parameters may include a relative velocity between the polishing surface and the surface of the substrate. A chemical solution with a concentration may be delivered to the polishing surface, and one of the plurality of process parameters may be the concentration.

In various aspects of the invention, a method for polishing a surface of a substrate includes transporting a fluid to a polishing surface and controlling the temperature of the fluid.

A potential advantage of the chemical mechanical polishing apparatus described herein is that it can significantly reduce temperature variations during a polishing operation and from one polishing operation to the next. This, in turn, can improve the repeatability of the polishing process.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a block diagram of the main components of a chemical mechanical polishing system as described herein;

FIG. 2 is a block diagram of a control system for controlling the carrier head in a polishing apparatus, such as the polishing apparatus of FIG. 1; and

FIG. 3 is a block diagram of the main components of a chemical mechanical polishing system constructed according to various implementations of the present invention.

Like reference symbols in the various drawings indicate like elements.

### DETAILED DESCRIPTION

The invention described herein generally relates to methods and apparatus for chemical mechanical polishing of substrates in order to planarize such substrates. Applicants have discovered that the planarization efficacy of CMP processing relates to the temperature of the process and temperature variation during the process. In particular, it is believed that CMP side effects such as erosion and dishing are related to temperature and temperature variation during the CMP process. In particular, Applicants have discovered, for example in CMP of copper using a slurry with ammonium persulphate (APS) oxidizer, that dishing and erosion can depend on the temperature at the surface of a polishing pad and the temperature of the polishing slurry, where dishing is increased with decreasing temperature, and erosion is increased with increasing temperature. Accordingly, the apparatus and methods described below are directed towards controlling the average temperature and reducing temperature variation during CMP planarization of substrates, particularly towards a target temperature that improves planarization. The described methods and apparatus lead to improved planarization efficacy during CMP of substrates, with reduced side-effects such as erosion and dishing.

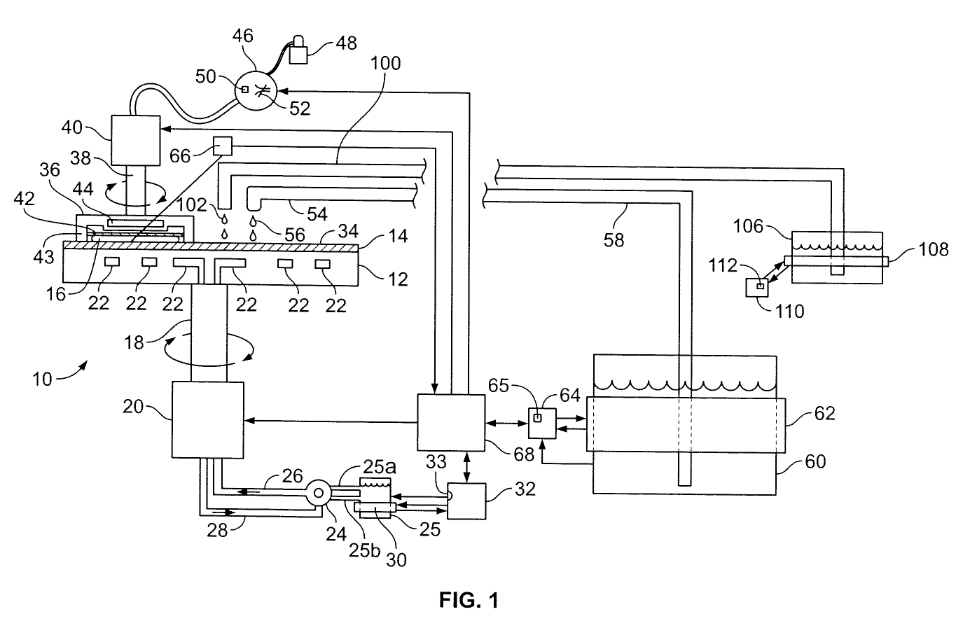

Referring to FIG. 1, a chemical mechanical polishing (CMP) apparatus 10 includes a flat platen 12 with an attached or applied polishing pad 14. Platen 12 is mounted on the end of a drive shaft 18 of a motor 20, which rotates platen 12 during a polishing operation. Platen 12 may be made of a thermally conductive material, e.g., aluminum, and can include within its interior an array of fluid circulation channels 22 through which a coolant or heating fluid can be circulated during use. A pump 24 collects fluid from a reserve tank 25 through a reservoir outlet tube 25a. Pump 24 supplies fluid to channels 22 via an inlet tube 26 and collects the fluid flowing out of circulation channels 22 through an outlet tube 28. Pump 24 returns fluid to reserve tank 25 through reservoir inlet tube 25b. A heating/cooling element 30 encircling reserve tank 25 can heat or cool the fluid flowing through the circulation system, e.g., to a predetermined temperature, thereby controlling the temperature of platen 12 during the polishing operation. The heating/cooling element can include heating and cooling elements known to the art. For example, a heating element can include a resistive electrical heating element, an infrared heating element, a heat exchanging system which directs a heated fluid through an exchange jacket or coil at reserve tank 25, and the like. A cooling element can include a heat exchanging system which directs a cooled fluid through an exchange exchange jacket or coil at the reserve tank 25, a Peltier element, and the like. A heating or cooling element can be employed to heat or cool platen 12 and a substrate at platen 12. For example, an infrared heating element can be employed to heat platen 12 and a substrate at platen 12. The infrared heating element can be positioned over the platen to direct infrared heat onto the polishing pad. A temperature controller 32, which includes a temperature sensor 33 for monitoring the temperature of the fluid, is electrically connected to heating/cooling element 30. Based on the signal supplied by sensor 33, controller 32 operates heating/cooling element 30, for example, to bring the fluid to a predetermined temperature.

Typically, polishing pad 14 is adhesively attached to platen 12. Polishing pad 14 can be, for example, a traditional polishing pad, a fixed abrasive pad, or the like. An example of a traditional pad is an IC1000 pad (Rodel, Newark, Del.). Polishing pad 14 provides a polishing surface 34.

A carrier head 36 faces platen 12 and holds the substrate during the polishing operation. Carrier head 36 is typically mounted on the end of a drive shaft 38 of a second motor 40, which can rotate head 36 during polishing and at the same time that platen 12 is also rotating. Various implementations may further include a translation motor that can move carrier head 36 laterally over the surface of polishing pad 14, for example, while carrier head 36 is rotating.

Carrier head 36 can include a support assembly, e.g., piston-like support assembly 42, which can be surrounded by an annular retaining ring 43. Support assembly 42 has a substrate-receiving surface, such as a flexible membrane, inside of the central open region within retaining ring 43. A pressurizable chamber 44 behind support assembly 42 controls the position of the substrate-receiving surface of support assembly 42. By adjusting the pressure within chamber 44, the pressure with which the substrate is pressed against the polishing pad can be controlled. More specifically, an increase in the pressure within chamber 44 causes support assembly 42 to push the substrate against polishing pad 14 with greater force, and a decrease in the pressure within chamber 44 reduces that force.

This document presents typical elements of the CMP apparatus that relate to the invention described herein. Additional details about the structure and operation of typical CMP are known, for example, U.S. Pat. No. 5,738,574, incorporated herein by reference in its entirety.

In various implementations, a pressure controller 46 in cooperation with source of pressure, e.g., a compressed air source 48 (e.g. container of pressurized air or a air pump) can control the pressure in chamber 44. Pressure controller 46 can include a pressure sensor 50 for sensing the pressure in chamber 44. Pressure sensor 50 is depicted within pressure controller 46, but may alternatively be located at any place from which the pressure within the chamber 44 could be effectively monitored. Pressure controller 46 operates a valve, e.g., electronically controllable valve 52, to flow air into chamber 44 and to release air from chamber 44, thereby controlling the pressure within chamber 44.

To perform the polishing operation, a supply delivery tube 54 delivers a polishing liquid 56 to the surface of polishing pad 14. In various implementations, polishing pad 14 comprises an abrasive, and polishing liquid 56 is typically a mixture of water and chemicals that aid in the polishing process. In some implementations, the polishing pad does not contain an abrasive, and polishing liquid 56 may contain an abrasive in a chemical mixture. In several implementations, both polishing pad 14 and polishing liquid 56 can include an abrasive.

A pipe 58 connects delivery tube 54 to a supply reservoir 60. A heating/cooling element 62 encircles reservoir 60 and provides a way of heating and/or cooling the polishing liquid, e.g., to a desired constant temperature, before it is delivered to the polishing pad. A temperature controller 64, which operates heating/cooling element 62, uses a thermal sensor 65 to monitor the temperature of the slurry and adjusts the power delivered to heating/cooling element 62 to control the slurry temperature.

An IR sensor 66 located at polishing surface 34 is oriented to sense the temperature of polishing surface 34 adjacent to carrier head 36, for example, when carrier head 36 is in contact with polishing surface 34. A programmed computer or special purpose processor 68 can monitor the output of IR sensor 66 and can control pump 24, temperature controller 32, pressure controller 46, and temperature controller 64, as described in greater detail below.

The polishing system can also include a pad rinse system, such as a water delivery tube 100 that delivers deionized water 102 to the surface 34 of polishing pad 14. A pipe 104 connects delivery tube 100 to deionized water tank 106. A heating/cooling element 108 encircles tank 106 and provides a way of heating and/or cooling the water before it is delivered to polishing pad 14. A temperature controller 110, which operates heating/cooling element 108, uses a thermal sensor 112 to monitor the temperature of the water and adjusts the power delivered to heating/cooling element 108 to achieve the desired water temperature.

During polishing, carrier head 36 holds substrate 16 against polishing surface 34 while motor 20 rotates platen 12 and motor 40 rotates carrier head 36. Supply delivery tube 54 delivers a mixture of water and a chemical to polishing surface 34. After polishing, debris and excess slurry can be rinsed from the pad surface by water from the water delivery tube 100.

During the polishing process, which is partially chemical in nature, the polishing rate depends on the temperature at of substrate 16 and polishing surface 34. More specifically, the polishing rate increases when the temperature increases and it decreases when the temperature decreases. Further, it is believed that undesirable side-effects such as erosion and dishing increase with temperature variation and/or temperature deviation, where dishing is increased with decreasing temperature, and erosion is increased with increasing temperature. To achieve a more uniform and repeatable polishing rate, and to reduce side effects such as erosion and dishing, temperature in CMP can be regulated, particularly towards a target temperature that improves planarization, in one or more ways as follows.

First, the temperature at polishing surface 34 can be partly regulated by controlling the temperature of the fluid circulating through fluid circulating channels 22. Because the platen is made of a thermally conductive material, the temperature of the fluid in the channels can directly and quickly influence the temperature of the polishing pad. Computer 68 can set a target temperature of temperature controller 32, then adjusts the power delivered to heating/cooling element 30 to control the temperature of the fluid, e.g., holding it at the target temperature. Thus, the target temperature can be reached, and temperature variations can be reduced.

The temperature at polishing surface 34 may also be regulated by controlling the temperature of liquid that is delivered to polishing surface 34. Polishing pad 14 may have insulating properties. Therefore, even if the temperature of platen 12 is controlled as described above, it may not provide as much control of the temperature of polishing surface 34 as desired. Additional temperature control at polishing surface 34 may include delivering liquid at a controlled temperature to polishing surface 34, such as polishing fluid 56, delivered through liquid delivery tube 54. Temperature controller 64 senses the temperature of the polishing fluid in tank 62. Computer 68 can set a target temperature, and temperature controller 64 can then adjust the power delivered to heating/cooling element 62 to control the temperature of the fluid, e.g., to the target temperature. Thus, the target temperature can be reached, and temperature variations can be reduced.

A second liquid delivered to surface 34 can be deionized water 102, delivered through water delivery tube 100. Temperature controller 110 can sense the temperature of the water in water tank 106. Temperature controller 106 can adjust the power delivered to heating/cooling element 108 to control the temperature of the water, e.g., to a pre-set target temperature. Water delivery tube 100 delivers deionized water, e.g., at a target temperature, to polishing surface 34, for example, for several seconds prior to the initiation of a polishing step. The polishing surface 34 can thereby be brought to the target temperature when the polishing step begins. This procedure can improve process repeatability.

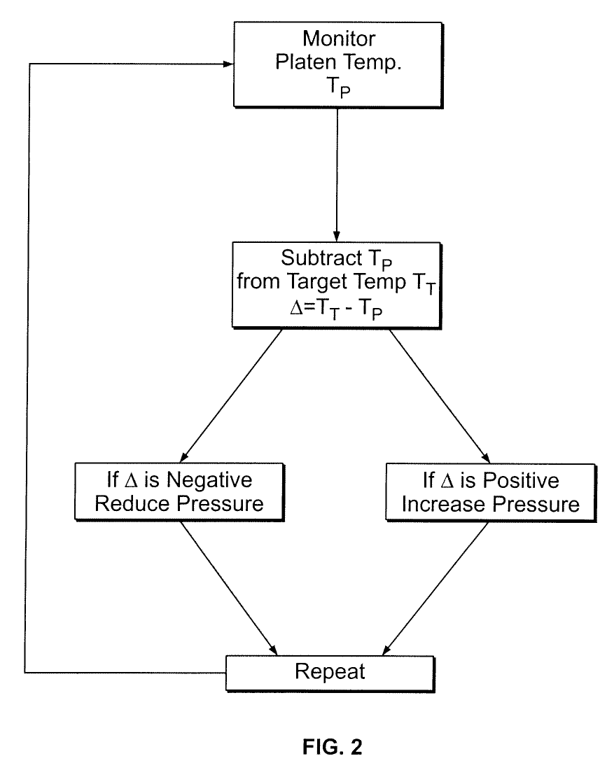

Referring also to FIG. 2, the temperature of substrate 16 during a CMP process can also be controlled by controlling the pressure with which substrate 16 is pressed against polishing surface 34 during polishing. The pressure between substrate 16 and surface 34 in part determines the friction. Increasing the pressure results in a higher friction and thus a higher temperature; conversely, decreasing the pressure results in lower friction and thus a lower temperature. Thus, computer 68 can vary the pressure in order control the temperature of polishing surface 34, for example, towards a target temperature or to reduce temperature variation.

The pressure which substrate 16 exerts against polishing surface 34 during processing can be controlled in the following manner. Using IR sensor 66, computer 68 can monitor the temperature of polishing surface 34. Computer 68 can be programmed to compare the temperature at sensor 66 to a predetermined target temperature profile. If the measured temperature is above the target temperature profile, computer 68 causes pressure controller 46 to reduce the pressure applied to substrate 16, e.g. by reducing the pressure in the chamber 44 in carrier head 36 (see FIG. 1). If the measured temperature is below the target temperature profile, computer 68 can cause pressure controller 46 to increase the pressure applied to substrate 16 by increasing the pressure in chamber 44. Thus, computer 68 can control the temperature, for example at a predetermined target value throughout the polishing process. This process can be as short as 1-2 minutes for a given substrate.

Typically, during a polishing run the temperature of polishing surface 34 will increase until a stable temperature is reached. One approach for establishing the target temperature to be used by computer 68 is to monitor a “good” polishing run to examine temperature variation throughout the run as a function of time, and at a fixed pressure. This measured temperature can be selected as the target temperature for similar runs. That is, computer 68 simply controls the pressure applied to the substrate for each run so that the temperature of the polishing surface follows the measured curve of a good polishing run. Thus, computer 68 tends to ensure that the averaged polishing rate of each polishing run is repeatable, thereby providing consistent results. A “good polishing run” occurs when temperature control leads to effective planarization with an acceptable amount of dishing and/or erosion.

The temperature of substrate 16 during a CMP process can also be controlled by controlling the relative velocity with which platen 12 and carrier head 36 rotate with respect to each other. The friction between substrate 16 and surface 34 is determined in part by the relative velocity between substrate 16 and surface 34. The relationship between the relative velocity and friction can be calculated. Then, the relative velocity can be adjusted to decrease friction if the temperature of polishing surface 34 is too high, or to increase friction if the temperature of polishing surface 34 is too low. For example, computer 68 can vary rotational velocities generated by motor 20 and/or motor 40 in order to control the temperature of polishing surface 34, e.g., towards a target temperature.

The relative velocity between platen 12 and carrier head 36 can be controlled in the following manner. Using IR sensor 66, computer 68 monitors the temperature of polishing surface 34. Computer 68 can be programmed to compare the sensed temperature to a predetermined target temperature profile. If the measured temperature is above or below the target temperature profile, computer 68 can proportionately changes the rotational velocity of motor 20 and/or motor 40. Thus, computer 68 controls the temperature, e.g., at a predetermined target value during the polishing process.

Typically, during a polishing run the temperature of polishing surface 34 will increase until a stable temperature is reached. In various implementations, the target temperature used by computer 68 can be selected by monitoring a “good” polishing run to examine temperature variation throughout the run as a function of time, while at a fixed relative velocity of substrate 16 to polishing surface 34. This measured temperature can be selected as the target temperature for similar runs. Thus, computer 68 can control the relative velocity between substrate 16 and polishing surface 34, so that the temperature of the polishing surface follows the measured curve of a good polishing run. Thus, computer 68 tends to ensure that the averaged polishing rate of each polishing run is repeatable, and thus leads to consistent results. A “good polishing run” occurs when temperature control leads to effective planarization with reduced dishing and/or erosion.

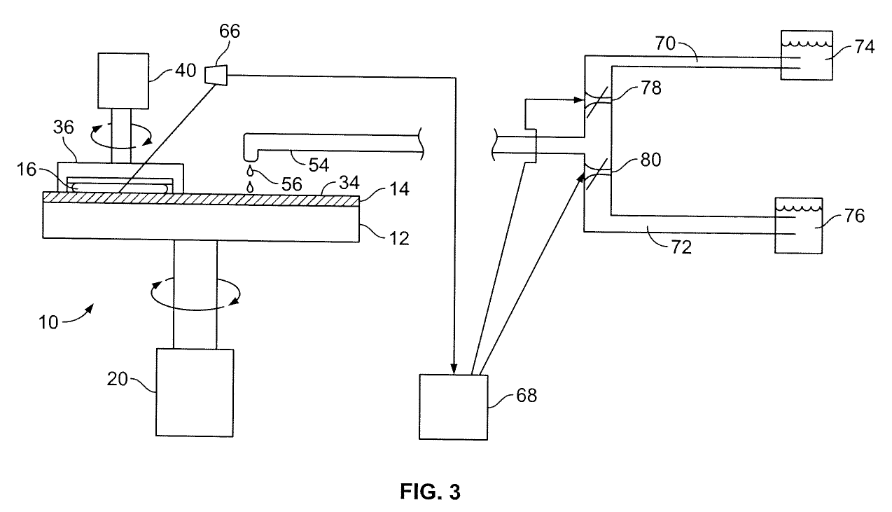

Referring to FIG. 3, the temperature of substrate 16 during a CMP process can be controlled by controlling the composition of polishing liquid 56. Polishing liquid 56 is delivered to polishing surface 34 by supply/rinse tube 54. Pipes 70 and 72 connect tube 54 to chemical solution reservoir 74 and water tank 76, respectively. Valves 78 and 80 control flow of liquid from pipes 70 and 72 to tube 54, respectively. Computer 68 can control valves 78 and 80. The temperature of substrate 16 can depend in part on the rate of reaction of polishing liquid 56 with a surface of substrate 16. The rate of reaction of polishing liquid 56 with a surface of substrate 16 can be directly proportional to the polishing rate. Increasing the concentration of chemical solution can increase the rate of reaction, and hence can increase the polishing rate. Decreasing the concentration of chemical solution can decrease the rate of reaction, and hence can decrease the polishing rate.

The composition of polishing liquid 56 can be controlled in the following manner. Using IR sensor 66, computer 68 can monitor the temperature of polishing surface 34. Computer 68 can be programmed to compare the sensed temperature to a predetermined target temperature profile. If the measured temperature is above the target temperature profile, computer 68 can adjust valve 78 to decrease the flow of chemical solution from chemical solution reservoir 74. Alternatively, computer 68 can adjust valve 80 to increase the flow of water from water tank 76. This adjustment or adjustments can decrease the concentration of the chemical solution on polishing surface 34, thus decreasing the polishing rate. On the other hand, if the measured temperature is below the target temperature profile, computer 68 can adjust valve 78 to increase the flow of chemical solution from chemical solution reservoir 74. Alternatively, computer 68 can adjust valve 80 to decrease the flow of water from water tank 76. This adjustment or adjustments can increase the concentration of the chemical solution on polishing surface 34, thus increasing the polishing rate.

Typically, during a polishing run the temperature of polishing surface 34 will increase until a stable temperature is reached. In various implementations, the target temperature used by computer 68 can be established by monitoring a “good” polishing run to examine temperature variation throughout the run as a function of time, and with a fixed concentration of chemical solution in water. This measured temperature can be selected as the target temperature for similar runs. Thus, computer 68 can control the concentration of the chemical solution in water, so that the temperature of the polishing surface follows the measured curve of a good polishing run. Computer 68 thus tends to ensure that the averaged polishing rate of each polishing run repeatable, leading to consistent results. A “good polishing run” occurs when temperature control leads to effective planarization with reduced dishing and/or erosion. If the measured temperature varies from the target temperature by more than a threshold amount, one or more of the polishing parameters, e.g., the pressure on the substrate, pressure on the retaining ring and/or slurry flow rate, can be adjusted to bring the temperature back toward the target temperature. The target temperature can be a constant through the polishing process. Moreover, the actual polishing rate can be allowed to drift during polishing, i.e., the feedback loop for the polishing parameters is based on keeping the temperature constant rather than keeping the polishing rate constant.

Other embodiments are within the following claims. For example, in systems in which coolant can be delivered to the platen to regulate the temperature of the polishing surface, the platen can be made of any appropriate thermally conducting material, besides aluminum as described above. In addition, instead of measuring the temperature of the polishing surface with an IR monitor, other known techniques for measuring the temperature of the polishing surface can be employed, e.g. a thermocouple installed in the platen or embedded in the polishing pad. Also, other ways of controlling the pressure between the substrate and the polishing pad may be employed. For example, rather than applying pressure to the backside of the substrate, the entire carrier head can be moved vertically by an actuator (e.g., a pneumatic actuator, electromagnetic actuator, or the like) to control the pressure on the substrate. Furthermore, the temperature of the polishing liquid or water delivered to the polishing surface can be controlled by heating or cooling elements placed at locations in the delivery systems other than the locations described. In addition, liquid may be delivered to the polishing surfaces through multiple delivery tubes, with an independent temperature controller controlling the temperature of the liquid in each tube.

A multi-step metal polishing process, e.g., copper polishing, can include a first polishing step in which bulk polishing of the copper layer is performed at a first platen with a first polishing pad without temperature control but using an in-situ monitor to halt the polishing step, and a second polishing step in which the barrier layer is exposed and/or removed and using the temperature control procedure discussed above.

A number of embodiments of the invention have been described. Nevertheless, it will be understood that various modifications may be made without departing from the spirit and scope of the invention.

What is claimed is:

1. A chemical mechanical polishing apparatus comprising:
a platen for holding a pad having a polishing surface;
a subsystem for holding a substrate against a polishing surface during a polishing process; and
a temperature sensor oriented to measure a temperature of the polishing surface, wherein the subsystem receives the temperature measured by the sensor and is programmed to vary a polishing process parameter in response to the measured temperature.

2. The apparatus of claim 1 wherein the subsystem holds the substrate against the polishing surface with a controlled pressure, and the polishing process parameter comprises the controlled pressure.

3. The apparatus of claim 2 wherein said subsystem includes a carrier head for holding the substrate during processing.

4. The apparatus of claim 3 wherein said subsystem includes a pressure controller for controlling the pressure with which the subsystem holds the substrate against the polishing surface.

5. The apparatus of claim 4 wherein said subsystem includes a processor which is electrically connected to said pressure controller.

6. The apparatus of claim 4 wherein said pressure controller controls the pressure by regulating a flow of compressed fluid to and from said carrier head.

7. The apparatus of claim 1 wherein said subsystem holds the substrate against the polishing surface with a relative velocity and the polishing process parameter comprises the relative velocity.

8. The apparatus of claim 1, further comprising a chemical solution delivery system for delivering a chemical solution with a concentration to the polishing surface and wherein the polishing process parameter comprises the concentration.

9. A chemical mechanical polishing apparatus comprising:
a platen for holding a pad having a polishing surface;
a fluid delivery system for transporting a fluid from a source to the polishing surface; and
a temperature controller which during operation controls the temperature of the fluid transported by the delivery system.

10. The apparatus of claim 9, further comprising a heating/cooling element for adjusting the temperature of the fluid.

11. The apparatus of claim 9, further comprising a processor for controlling the temperature of the fluid.

12. The apparatus of claim 9 wherein the source is a water tank.

13. The apparatus of claim 9, further comprising an infrared heat source.

14. A method for polishing a surface of a substrate, said method comprising:
polishing the surface of the substrate with a polishing surface during a polishing process characterized by a plurality of process parameters;
repeatedly monitoring a temperature of the polishing surface during the polishing process; and
controlling one of the plurality of process parameters in response to the monitored temperature so as to achieve a target value for the monitored temperature.

15. The method of claim 14, wherein one of the plurality of process parameters is a controlled pressure with which the substrate is held against the polishing surface.

16. The method of claim 15, wherein controlling the controlled pressure comprises increasing the pressure if the monitored temperature is below the target temperature.

17. The method of claim 15, wherein controlling the controlled pressure comprises decreasing the pressure if the monitored temperature is above the target temperature.

18. The method of claim 14, wherein one of the plurality of process parameters comprises a relative velocity between the polishing surface and the surface of the substrate.

19. The method of claim 14, further comprising:
delivering a chemical solution with a concentration to the polishing surface, wherein one of the plurality of process parameters comprises the concentration.

20. A method for polishing a surface of a substrate, said method comprising:
transporting a fluid to a polishing surface; and
controlling the temperature of the transported fluid.
